(19) United States
(12) Patent Application Publication
(10) Pub. No.: US 2009/0309573 A1
(43) Pub. Date: Dec. 17, 2009

(54) DETERMINING OUTPUT VOLTAGE OR CURRENT IN AN SMPS

(75) Inventors: Peter Lurkens, Aachen (DE); Christian Hattrup, Wurselen (DE); Thomas Scheel, Stolberg (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 12/373,962

(22) PCT Filed: Jul. 12, 2007
(86) PCT No.: PCT/IB07/52779

§ 371 Date: Jan. 15, 2009

(30) Foreign Application Priority Data
Jul. 21, 2006 (EP) 06117640.0
Jul. 6, 2007 (EP) 07111926.7

(51) Int. Cl. G01R 19/00

(52) U.S. Cl. 324/76.11

(57) ABSTRACT

An apparatus and method for determining an output voltage or output current in an SMPS circuit 10 are described. The SMPS circuit comprises a switching element 18 which in operation is switched according to consecutive switching cycles. An electrical value I_{L} within the SMPS circuit 10 is compared to a reference value I_{ref}. The electrical value I_{L} varies within the switching cycle such that is equal to the reference value at least once during each cycle. The comparator signal comp is evaluated to determine timing information t of an instant of change in the signal. The timing information t is used for determining the output voltage V_{out,Av} or output current I_{out,Av}.

### FIELD OF THE INVENTION

The present invention relates to determining an output voltage or output current in a power supply circuit, and more specifically to an apparatus and a method determining these values in a power supply circuit comprising a voltage input and at least one switching element, which in operation is switched according to consecutive switching cycles.

### BACKGROUND OF THE INVENTION

Power supply circuits which transform an input voltage into an output voltage and/or current to drive a load that use a switching element switched according to consecutive switching cycles are known as switched mode power supplies (SMPS). Many different topologies of SMPS circuits are known, including non-resonant topologies, where the switching frequency is significantly away from the resonant frequency of resonant elements in the circuit as well as resonant topologies, where the switching frequency is near the resonant frequency of a resonant element.

During operation of such SMPS circuits, it is desirable to be able to obtain information on the output current and/or voltage, e. g. for information purposes, to achieve control or for other reasons. This information may be obtained straightforward by sensing the electrical values directly. To obtain digital values for use in further processing, e. g. control applications, the sensed values need to be converted by A/D converters. In SMPS circuits operated at high switching frequency, very fast A/D converters are needed to achieve a corresponding time resolution.

US 2005/0265058 A1 describes a system and method for regulating resonant inverters. A high frequency resonant inverter comprises a half bridge that converts a DC input voltage to a square wave AC output to drive a resonant tank comprising a resonant inductor and two resonant capacitors. The inverter is controlled by regulating the phase angle between mid-point voltage of the half-bridge and the inductor current or inductor voltage. The inductor voltage or current is sensed by a sensor and compared to a reference value by a comparator. The reference value may be ground potential. A digital controller detects the inductor voltage or current zero crossings and computes the required time delays from the zero-crossings to achieve the desired phase and duty cycle of the inverter. This part may be considered as a first control loop regarding the phase angle between inverter voltage and current. Output voltage and current, measured by a common sensor, are fed back to a regulating circuit, which may thus control output power, output current or output voltage by commencing an appropriate phase angle to the first control loop.

US 2005/0265058 A1 thus describes direct digital phase control, but still employs conventional sensing and control of the current and the voltage at the load.

### OBJECT OF THE INVENTION

It is an object of the present invention to propose an apparatus and method for determining output voltage and/or output current in a way suited for high bandwidth applications.

### SUMMARY OF THE INVENTION

This object is achieved by an apparatus according to claim 1 and a method according to claim 12. Dependent claims refer to preferred embodiments of the invention.

In the apparatus a method according to the invention, output voltage and/or output current are determined without direct sensing and without the use of ADCs. Instead, a binary comparator signal is generated by comparing one or more electrical values, different from the value that is to be determined, within the power supply circuit to reference values. The thus monitored electrical values, which include voltage and/or current signals within the circuit, or be derived from such a value, is chosen such that it varies within each of the consecutive switching cycles, and the reference value is chosen such that the electrical value is equal to the reference value at least once during each cycle. The binary comparator signal indicates by its binary value if the varying electrical value is above or below the reference value, and at which time.

According to the inventive apparatus and method, the binary comparator signal is evaluated by regarding at least one instant of change in the comparator signal, and by determining timing information related to this change. As will be explained in further detail below, the timing information may relate to the occurrence of at least one instant of change within a fixed switching interval, i. e. the duration of a timing interval between a switching instant of the switching element and the instant of change. Alternatively, other timing information such as the relative timing of several instants of change in the comparator signal, or more complex time intervals between defined time instants may be obtained.

According to the invention, the output voltage or output currents are determined from the timing information. This may preferably be effected in a digital calculation unit. As will be shown below, the calculation necessary to obtain the desired values may be obtained from knowledge about the topology, components and operation of the power supply circuit, and may yield the electrical output values in a simple, straightforward way.

The invention thus eliminates the need for separate sensing of the output values. Especially, the invention does not necessitate A/D converters, but uses one or more comparators as less expensive, yet considerably faster components. As a consequence, a high bandwidth current and/or voltage measurement at the output is possible, and the result may be directly available as a digital value.

The electrical output (voltage and/or current) may be DC or AC. The quantity determined for the output values is preferably a time average value, at least a time average value within the duration of one switching cycle.

The calculation necessary for determining the electrical output values based on the timing information may be derived from a prior evaluation of the power supply circuit and the waveforms produced therein. For SMPS circuits of known topologies, components and operation, it is possible to determine template functions describing the variation of at least one electrical value within the circuit over time. The determination of such a template function may be made either analytically or numerically. In both cases, suitable approximations may be made, depending on the desired accuracy. As will be shown in connection with the preferred embodiments for several, significantly differing topologies of both resonant and non-resonant SMPS circuits, such template functions may be derived by the skilled person. Of course, this analysis needs to be performed only once, and the resulting calculation, i. e. a formula which yields the desired value(s) directly, may be obtained and implemented in the apparatus.

There are various further features relating to preferred embodiments of the invention. Preferably, the reference value is chosen to be constant, at least constant within each of the switching cycles. It is especially preferred to use a zero reference value, which is easy to provide without problems.

Preferably the timing information comprises at least one timing value indicating the duration of the time interval. Such a time interval may be defined between a switching instant of the switching element and the described instant of change in the comparator signal. Of course, the interval may be defined both starting at a switching instant and ending with an instant of change, as well as starting with an instant of change and ending with a switching instant. Furthermore, if several signals are used, also the time between instants of change can be used. In a preferred embodiment, a digital counter is provided which counts clock pulses within a time period that starts and/or ends with an instant of change of the comparator signals. Thus, a digital value for the duration of accordingly defined intervals is instantly and easily obtained.

The invention is applicable to a wide range of power supply circuits. In a preferred embodiment, the power supply circuit comprises a voltage input and at least one switching element supplying an input voltage as a switched voltage to a reactive element connected to an output part. The output part delivers the output voltage or current that is to be determined. The switching element may comprise any configuration of switches, e. g. a single switch, a half bridge or a full bridge. The reactive element may comprise one or more inductance, capacitors etc. The switching element is switched within the switching cycles to form the desired output. The type of operation, e. g. how the switching element is switched, can be any known type, especially comprising resonant (i. e. switching frequency near the resonant frequency, such that substantially sinusoidal waveforms are achieved) and non-resonant modes of operation. Switching frequency, duty cycles and other parameters may be fixed or variable. The topology chosen may be any suitable SMPS topology, including, but not limited to, buck, boost, buck-boost, fly back, LLC, LC, LCC, forward, SEPIC etc.

Preferably, the electrical value regarded is a current through at least one reactive element or a voltage over the reactive element. In preferred embodiments, which will be explained in detail below, the reactive element is an inductor, and the regarded electrical value is a current through this inductor, which is compared by the comparator to the mentioned reference value. This is especially preferred in topologies, where the mentioned inductor is connected in series between the switching element and the output part of the power supply circuit, which delivers the output voltage or current.

While the above described apparatus may be a separate unit, used to determine output values in a power supply circuit, it may also be part of a power supply circuit. Preferably, the means for determining the output values, e. g. a digital logical unit, or in more complex cases a microcontroller or DSP may be used both for these calculations and for driving and/or controlling the power supply circuit itself.

### BRIEF DESCRIPTION OF THE DRAWINGS

The above and other objects, features and advantages of the present invention will become apparent from the following description of preferred embodiments, in which:

FIG. 1 shows as a symbolic diagram of a converter circuit and an embodiment of an apparatus according to the invention;

FIG. 2 shows a circuit diagram of a buck converter;

FIG. 3 shows a schematic time diagram of the current IL in the circuit of FIG. 2;

FIG. 4 shows a circuit diagram of a fly back converter;

FIG. 5 shows schematic timing diagrams of electrical values in the circuit of FIG. 4;

FIG. 6 shows a circuit diagram of a series resonant converter;

FIG. 7 shows a schematic timing diagram of electrical values in the circuit of FIG. 6;

FIG. 8a shows a locus diagram of the converter operation of the circuit of FIG. 6;

FIG. 8b shows a locus diagram of the switching of the rectifier in FIG. 6 and

FIG. 8c shows a locus diagram of converter switching of the circuit as shown in FIG. 6.

### DETAILED DESCRIPTION OF PREFERRED EMBODIMENTS

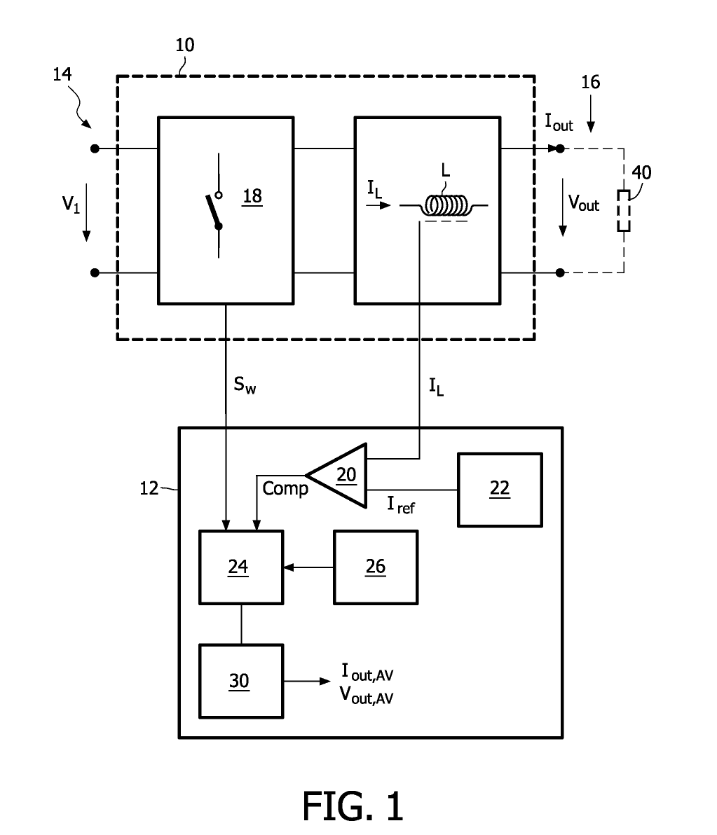

FIG. 1 shows in schematical form the general structure of a power supply circuit 10 with an apparatus 12 for obtaining digital values of the time average digital output current of the circuit 10.

Power supply circuit 10 is a switched mode power supply (SMPS). The circuit 10 has an input terminal 14 where an input voltage V₁ is applied and an output terminal 16, at which an output voltage Vₒᵤₜ and an output current Iₒᵤₜ are delivered to a connected load 40.

The power supply circuit 10 may be any out of a plurality of known switching mode power supplies, which may accept and deliver both AC and DC input and output. The SMPS 10 has one or more switching elements 18 which in operation are switched according to consecutive switching cycles as will be explained below. The switching element 18 may be of any type, e. g. including a single switch, half bridge or full bridge. The SMPS 10 comprises further circuitry according to the chosen topology and specific implementation. In the example shown, there is provided an inductance L with an inductor current I_{L} through the inductor L which is time variant within each of the switching cycles of switching elements 18.

The current value I_{L} is sensed and delivered as an analog value to the apparatus 12. Further, apparatus 12 receives a digital signal S_{w} which indicates the switching state of switching element 18.

Apparatus 12 comprises a comparator 20 which compares the time-variant current signal I_{L} to a fixed referenced value I_{ref} generated by a reference signal unit 22. As will be explained later, the reference value may be a zero value, so that no unit 22 is necessary.

Apparatus 12 solely relies on the comparator output signal comp, which is a binary signal, and the timing information about the switching cycle S_{w} to determine time-average values I_{out,AV} and V_{out,AV} of the output current and output voltage.

To determine these time average values, a logical unit 24 evaluates relative timing of the comparator signal comp and the information about the switching cycle timing S_{w} with relation to clock pulses from a clock 26 to determine a digital timing value t. The value t represents a time duration (i. e. number of clock pulses) of a time interval which is defined between an occurrence of change within the switching state S_{w} of switching element 18 and an instant of change within comparator signal comp. For example, t may indicate the time duration from the start of a switching cycle, at which the switching element 18 is switched on until the instant at which the time-variant current I_{L} reaches a reference value I_{ref}, so that a change in the comparator signal occurs. As will become apparent in connection with the discussion of the preferred embodiments, a plurality of different definitions of the timing interval t may be used, depending on topology and operation of the circuit 10.

In a processing unit 30, the timing value t delivered for each switching cycle of SMPS 10 is evaluated to deliver I_{out,AV} and/or V_{out,AV}. This calculation is done according to a predetermined function implemented in calculation unit 30 which yields the desired values I_{out,AV}, V_{out,AV} in dependence on the delivered timing value t.

Of course, the corresponding calculation relies on detailed knowledge of topology, component values and mode of operation of the SMPS circuit 10.

The specific calculation for a given SMPS 10 may be derived by analyzing the time-variant behavior of the chosen electrical quantity (in the example: I_{L}) within the circuit in terms of a template function. Examples of such template functions for specific embodiments will be given below. Evaluation of such a template function with regard to the output values will yield, as an approximation or exact calculation, a functional dependence of the desired parameters I_{out,AV} and/or V_{out,AV} on the timing values t, where this functional dependence preferably only includes further constant or readily available values, such as, e. g. electrical component values of components of the circuit 10 or the electrical input to the circuit 10 at input terminal 14.

It should be emphasized that while the preferred embodiment of FIG. 1 shows an apparatus 12 with separate, dedicated elements such as logical unit 24 and calculation unit 30, one or more of these may be realized in a common assembly, especially as elements of a software executed on a microcontroller or signal processor or ASIC.

The switching frequency of the SMPS circuit 10 will generally be higher than 1 kHz, and in many cases significantly higher, e.g. up to some 100 kHz. In each switching cycle, the output values I_{out,AV} and V_{out,AV} may be determined as values averaged over the time of the corresponding switching cycle. Thus, logical unit 24 and calculation unit 30 need to be able to perform the described evaluation once within each switching cycle of SMPS 10. Alternatively, it is also possible to evaluate the delivered timing values t not in every cycle, but only in a subset of an available cycles, e. g. every other cycle. Also, it is possible to store continuously calculated values t in a register, and thus decouple post-processing in unit 30 from the actual switching speed. In this way it is possible to use relatively slow speed microprocessors, or to effect very complicated calculations.

In the following, detailed examples of SMPS circuits will be explained and the corresponding definition of timing values t and functional dependence of the desired output values on these timing values will be derived.

### FIRST EXAMPLE

### Buck Converter

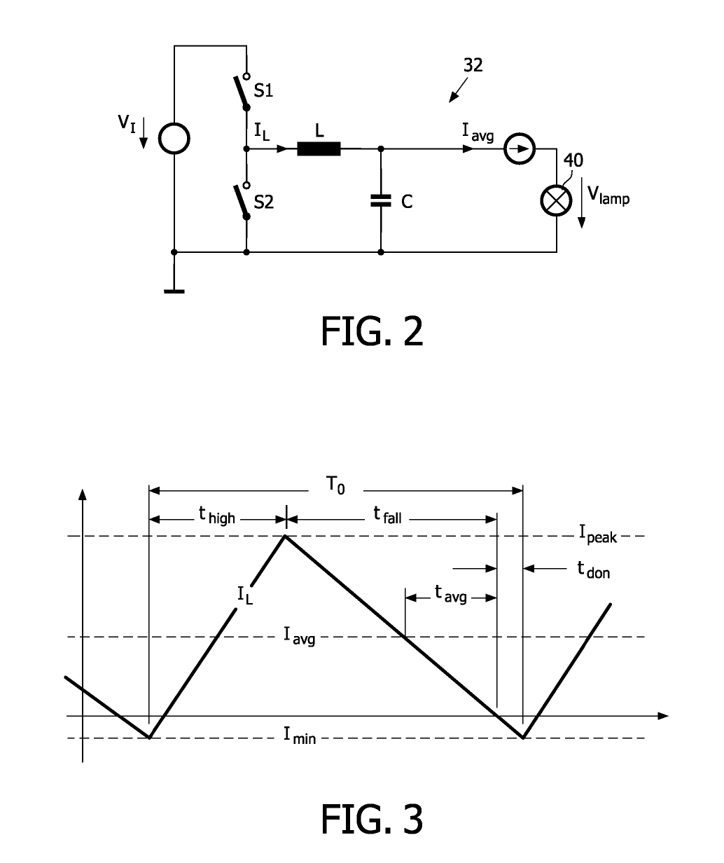

In a first example, the power supply circuit 10 will be assumed to be a buck converter 32 as shown in FIG. 2. In this very simple circuit, an input voltage V₁ is switched by a half bridge of switching elements S1, S2. A series inductance L and a parallel capacitance C are provided. Switches S1 and S2 are switched in alternating fashion. During a time thigh, switch S1 is closed while S2 is open, so that a current I_{L} through the inductance L increases. Subsequently, S1 is opened and S2 closed, so that I_{L} decreases. The continuous switching leads to an average current I_{AVG} delivered to the load 40. A corresponding circuit was realized as a power supply for an UHP lamp, where the measurement of the average lamp current was done by the apparatus 12 by only detecting the zero crossings of the current in the soft-switching down converter state. Since there is only very little variation of the lamp current during a switching cycle, the load 40 may here assumed to be a constant current sink.

FIG. 3 shows a timing diagram of the operation of buck converter 32. For reasons of simplicity we consider here a steady state operation. The switching occurs in a timing interval T₀. During t_{high}, I_{L} is shown to increase (the shown linear increase here is an approximation of a more realistic, non-linear curve). In the remainder of interval T₀, the current I_{L} drops. After a time t_{fall}, current I_{L} reaches a value I_{ref} (which in this example will be assumed to be zero) and remains below for a following interval t_{don}. Thus, I_{L} alternates between a maximum value Iₚₑₐₖ and a minimum value Iₘᵢₙ, with a specific, yet unknown time average value I_{avg} and also an unknown lamp voltage V lamp.

The reference value I_{ref} is chosen from the interval Iₘᵢₙ <I_{ref}<Iₚₑₐₖ, so that t_{don} is the time interval from the time where the falling I_{L} reaches I_{ref} until the end of the switching period T₀, i.e. until the next switching event occurs. Note that in FIG. 3 I_{ref} is chosen to be zero, which is an easily detectable value.

From the definition of time intervals in FIG. 3, we may define a time interval t_{avg}, which corresponds to the duration between the time when I_{L} is equal to I_{avg}, and the time when I_{L} is equal to I_{ref}:

t_{avg}=½(t_{fall}−t_{don}).

For the time t_{fall}, during which S2 is closed and S1 is opened, we can calculate the slope of I_{L} as

$$\begin{matrix}d \frac{{I}_{L}}{d t} {\vert}_{{t}_{fall}} = \frac{- {V}_{lamp}}{L} \\ = \frac{- a \cdot {V}_{1}}{L} \\ = - \frac{{t}_{high}}{{T}_{0}} \frac{{V}_{1}}{L} .\end{matrix}$$

where V₁ is the input voltage, L is the inductance, Vₗₐₘₚ is the output voltage and a is the duty cycle. The above holds true for steady state operation. The transient case can be deduced also if the initial conditions are known.

For a general value of I_{ref}, it follows that the average current I_{avg} may be expressed in dependence on the known values for V₁, L and I_{ref} as well as timing values t_{high}, t_{fall}, t_{don} and T₀:

$$\begin{matrix}{I}_{avg} = - {t}_{avg} \cdot d \frac{{I}_{L}}{dt} + {I}_{ref} \\ = \frac{{t}_{high} \cdot ( {t}_{fall} - {t}_{don} )}{{T}_{0}} \cdot \frac{{V}_{1 }}{L} + {I}_{ref} .\end{matrix}$$

If I_{ref} is chosen to be zero, as in FIG. 3, the resulting average current I_{avg} may easily be calculated in dependence on known constants V₁, L as well as timing values t_{high}, t_{fall}, t_{don}. For the purposes of control in our example, t_{high} and t_{don} are chosen to be constant values. The only remaining value, t_{fall}, will result in operation as the time between a switching event (end of t_{high}: S1 is opened, S2 is closed) and the zero crossing of current I_{L}.

As shown in FIG. 1, the zero crossing of current I_{L} may easily be detected by a comparator 20 which compares I_{L} to zero. In order to be sure, that only the relevant zero crossing (end of t_{fall}: I_{L} changes from positive to negative, see FIG. 3) is detected, we define an auxiliary logical function as follows:

z_{Kk+1}=comp

S=z_{Kk}*( [symbol] comp)

This function processes the input signal (comparator signal) comp and determines an auxiliary signal S which only indicates the relevant zero crossing. This function, which may easily be implemented as a digital state machine, is indicated in FIG. 1 as block 24.

Within the calculation unit 30, the above given equation of I_{avg} is evaluated, so that in each switching cycle the actual value of I_{avg} is delivered.

It should be noted that instead of approximating I_{L} as shown in FIG. 3 by piecewise linear waveforms, it is also possible to perform a more precise consideration of the actual piecewise sinusoidal waveforms. A more exact approximation is not much more complicated. Since usually only small arguments of the sine-function apply, a linearization with a constant factor is easily possible.

### SECOND EXAMPLE

### Fly Back Converter

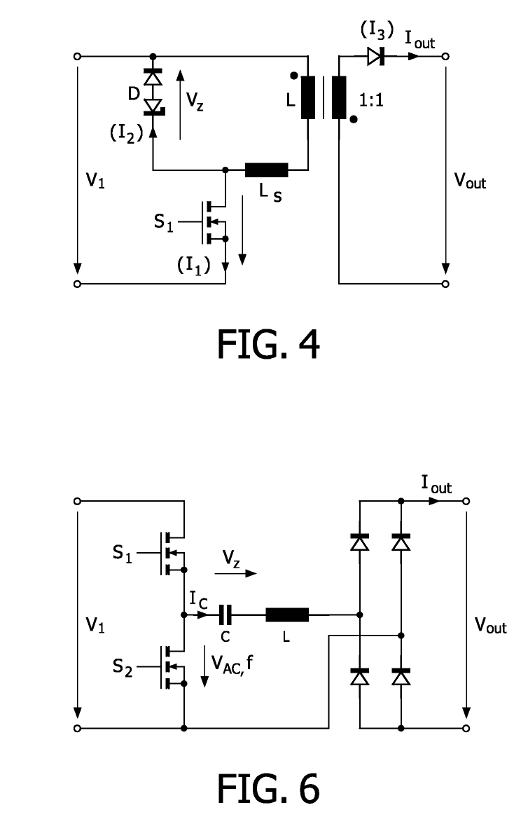

In a second example, SMPS circuit 10 is assumed to be a fly back DC/DC converter as shown in FIG. 4. The switch S₁ is cyclically turned on and off, such that a cycle is defined such that in each cycle S₁ is once switched on and off. The on-time of S₁ is a certain fraction (duty cycle) of the switching period. The control of the output current Iₒᵤₜ may be achieved e. g. by adjustment of the duty cycle. Depending on the load 40, the output voltage is either predetermined e. g. in case of a battery or some other voltage-source-type load, or settles as a consequence of the output current, as in case of a resistor-type load. In practical cases, even with resistive load, the output voltage is buffered by a capacitor (not shown) leading to a practically constant output voltage on a time-scale of a few switching cycles.

We assume that supply voltage, component dimensioning and switching frequency f are known. Based on this knowledge, it will now be shown how either I_{out,AV} or V_{out,AV} may be determined by the detection of the characteristic timing of a template function for a time-varying electrical value within the circuit of FIG. 4.

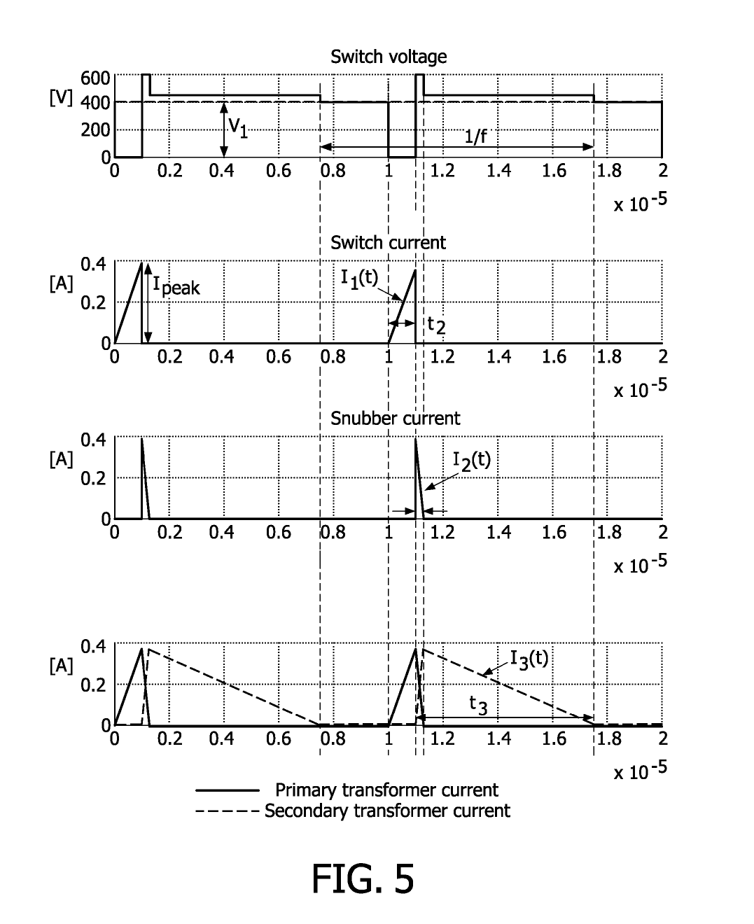

FIG. 5 shows typical time functions of voltage at the switch and currents in the converter.

As in the buck converter according to the first example, the typical waveforms of the currents are represented by piecewise linear segments. A speciality here is, that the leakage of the transformer leads to a partial overlap between secondary and primary current, reducing the total amount of output current. This can be calculated beforehand, if the voltage V_{Z} of the snubber element D is known. If the snubber voltage is not known, e.g. if it is realised by an RC-element, the template approach can be used still to detect the snubber voltage from the characteristic timing.

The current is composed from three template functions I₁, I₂ and I₃ which may be defined as follows:

$${I}_{1} ( t ) = \frac{{V}_{1}}{L + {L}_{s}} \cdot ( t - {t}_{0} ) , \\ current in the switch during {t}_{0} < t < {t}_{1}$$

$${I}_{2} ( t ) = {I}_{peak} - \frac{{V}_{Z} - {V}_{out }}{{L}_{s}} \cdot ( t - {t}_{1} - {t}_{0 } ) , \\ current in snubber during {t}_{1} < t < {t}_{2}$$

$${I}_{3} ( t ) = {I}_{peak} - \frac{{V}_{out}}{L} \cdot ( t - {t}_{1} - {t}_{0} ) , \\ current in secondary transformer winding during {t}_{2} < t < {t}_{3} .$$

In the interval t₁<t<t₂ the current in the secondary winding is I₃(t)−I₂(t).

Outside of their definition interval, all defined currents I₁, I₂ and I₃ are zero.

With these template functions, the occurrences of the events t₂ and t₃ in the current waveform are defined in dependency of characteristic quantities. The events t₀ and t₁ are a consequence of the control and known beforehand, and thus need not to be detected separately. The detection of the other events can be done by simple comparators, comparing the switch voltage against the supply voltage.

$${I}_{peak} = \frac{{V}_{1}}{{L}_{s} + L} \cdot {t}_{1}$$

$${t}_{3} = \frac{{I}_{peak} \cdot L}{{V}_{out}} \to {V}_{out} = \frac{{I}_{peak} \cdot L}{{t}_{3}} = \frac{{V}_{1} \cdot L}{{L}_{s} + L} \cdot \frac{{t}_{1}}{{t}_{3}}$$

$${t}_{2} = \frac{{I}_{peak} \cdot {L}_{s}}{{V}_{Z} - {V}_{out}} -> {V}_{Z} = \frac{{I}_{peak} \cdot {L}_{s}}{{t}_{2}} + {V}_{out} = \frac{{I}_{peak} \cdot {L}_{s}}{{t}_{2}} + \frac{{V}_{1} \cdot L}{{L}_{s} + L} \cdot \frac{{t}_{1}}{{t}_{3}}$$

The average output current is obtained by integrating the waveform elements of the secondary current over a switching interval and considering the switching frequency:

$${I}_{out} = f \cdot ( {\int }_{0}^{{t}_{3}} \frac{{V}_{out}}{L} \cdot t d t - {\int }_{0}^{{t}_{2}} \frac{{V}_{Z} - {V}_{out}}{{L}_{s}} \cdot t d t ) \\ = \frac{1}{2} \frac{{V}_{1}}{L + {L}_{s}} \cdot f \cdot {t}_{1} \cdot ( {t}_{3} - {t}_{2} )$$

Thus, it is possible to determine I_{out,AV} according to the above equation if timing values t₂, t₃ are known. These values may be derived from a comparator signal comparing the switch voltages V_{S} to the input voltage V₁. As shown in FIG. 5, V_{S} will be above V₁+V₂ for the time interval from t₁ to t₂, and V₁+V₂ for the time interval from t₂ to t₃, and subsequently V₁ for the remainder of the switching cycle. Consequently, the voltage V_{S} of the switch may be compared by two comparators to suitable threshold voltages. The derived comparator signal may be evaluated by logical unit 24 according to the above given definitions. Timing values t₂, t₃ may then be passed on to calculation unit 30 to determine the desired output values according to the above definition.

An alternative solution is to use the current in S₂ to determine t₂ and a comparator of V_{S} to determine t₃.

### THIRD EXAMPLE

### Resonant Converter

In the following third example, SMPS 10 will be assumed to be a series-resonant DC/DC converter as shown in FIG. 6, which converts a DC input voltage V₁ into a DC output voltage Vₒᵤₜ. Two power switches S₁ and S₂ are alternatively turned on, with a switching frequency f and an on-time of 1/(2×f) (i. e. in this example a constant duty cycle of 50%). The control of the output current is achieved by an adjustment of the switching frequency f. Depending on the load, the output voltage is either pre-determined, e.g. in case of a battery or some other voltage-source-type load, or settles as a consequence of the output current, as in case of a resistor-type load. In practical cases, even with resistive load, the output voltage is buffered by a capacitor (not shown) leading to a practically constant output voltage on a time scale of a few switching cycles.

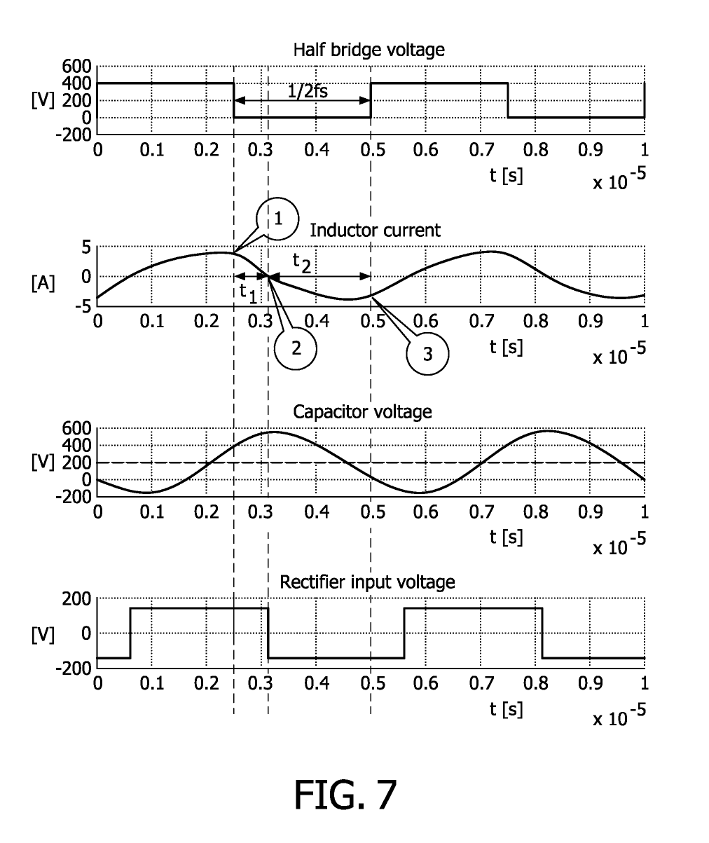

FIG. 7 shows typical time functions of voltage of the capacitor C, the current in the inductor L at a given frequency f, a given input voltage V₁, and a given (yet unknown) output voltage Vₒᵤₜ.

If, as given in the circuit of FIG. 6, a series connection of a capacitor and an inductor is connected to a constant voltage V, the time signals of the current perform sinusoidal oscillations with a characteristic frequency being the resonance frequency of the L-C circuit. In addition, the phase argument of the capacitor voltage is delayed by π/2, compared to the waveform of the inductor current. A useful choice for the template functions is now based on sinus functions, while amplitude and phase are unknown beforehand.

If initially the inductor current is zero, the amplitude of a current oscillation is determined by:

$${\hat{I}}_{L} = \frac{{V}_{0}}{{Z}_{C}} , {I}_{L} ( t ) = {I}_{L} \cdot sin ( ω t )$$

$$with$$

$${Z}_{C} = \sqrt{L / C} , {ω}_{C} = 1 / \sqrt{L \cdot C} , {V}_{0} = V - {V}_{C}$$

Hence the capacitor voltage in this special case is described by:

\hat{V}_{c}=V₀, V_{c}(t)=\hat{V}_{c} ·sin (ωt−π/2)+V₀

This means the initial voltage of the capacitor simply contributes linearly to the externally applied voltage. In particular, this holds true, even if during an ongoing oscillation, the applied voltage is changed at the zero crossing of the current.

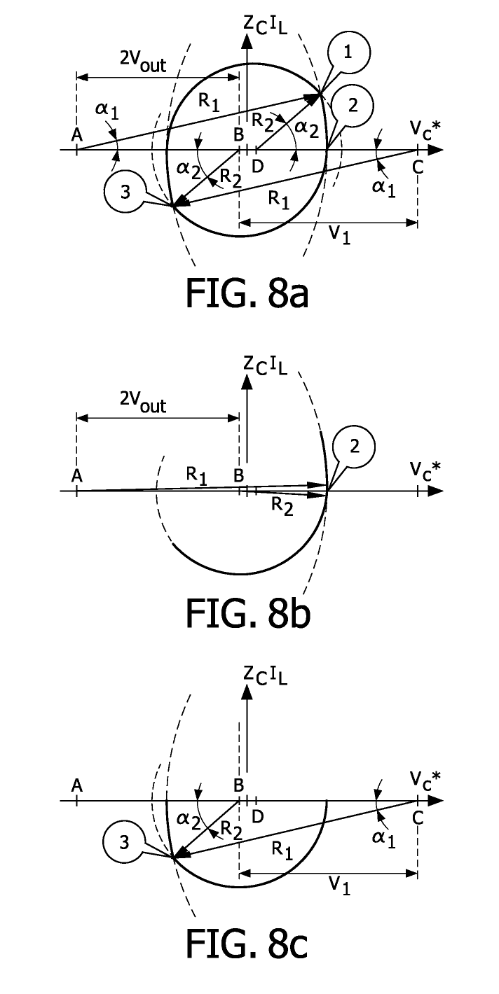

One can now show, that after removing constant offsets from the capacitor voltage (V_{C}) and transforming the capacitor current with the characteristic impedance ZC into a virtual voltage, the locus of the system state, described by inductor current and capacitor voltage progresses on contiguous segments of circles as shown in FIG. 8a.

After the converter from V₁ to 0 switched in the point 1, the locus proceeds during the time t₁ on the segment 1-2 with a large radius R₁ and the center at “A”. The angle of the segment α₁ is calculated as α₁=t₁·ω_{C}

When the inductor current crosses zero (point 2), the rectifier input voltage changes from+Vₒᵤₜ to −Vₒᵤₜ and the locus proceeds with smaller Radius R₂ on the segment 2-3 with a center at “B”. As this happens on the horizontal axis of the diagram, the distance A-B reflects the transition of the output rectifier (FIG. 8b)

Radius R₁ and R₂ are determined by:

R₁_{V}^{_{*}}½−V_{C01}+Vₒᵤₜ, R₂₌^{V}^{_{*}}½−V_{C01}−Vₒᵤₜ.

Hence:

R₁−R₂=2Vₒᵤₜ, note that the unknown capacitor voltage eliminates.

The locus continues to proceed on the segment 2-3 during the time intercal t₂. The angle α₂, indicating the difference to full 180°, or π, and as such the gap before the current crossing zero again is calculated as:

$${α}_{2} = π - {t}_{2} \cdot {ω}_{C} = π - ( {α}_{0} - {α}_{1} ) , {α}_{0} = \frac{{ω}_{C }}{2 {f}_{s}}$$

At the next switching event at point 3, the converter switches again from 0 to V₁, and the locus proceeds on a new segment with a center at “C” (FIG. 8c).

The distance B-C indicates again the switching voltage. Since this does not happen on the horizontal axis this time, the angles α₁ and α₂ have to be considered.

$${R}_{1} \cdot sin ( {α}_{1} ) = {R}_{2 } \cdot sin ( {α}_{2} ) , \\ {R}_{1} \cdot cos ( {α}_{1} ) = - {R}_{2} \cdot cos ( {α}_{2} ) = {V}_{1}$$

$${R}_{1} = \frac{sin ( {α}_{2} )}{sin ( {α}_{2} - {α}_{1} )} \cdot {V}_{1} , \\ {R}_{2} = \frac{sin ( {α}_{1} )}{sin ( {α}_{2} - {α}_{1} )} \cdot {V}_{1}$$

Considering the previous condition at point 2, Vₒᵤₜ can now be determined:

$${V}_{out} = \frac{{Z}_{C}}{2} ( {R}_{1} - {R}_{2} ) = \frac{{V}_{1}}{2} \frac{sin ( {α}_{2} ) - sin ( {α}_{1} )}{sin ( {α}_{2} - {α}_{1} )}$$

With the knowledge of Vₒᵤₜ, R₁ and R₂ can be determined and the average output current is obtained by integrating the template functions.

$${I}_{out , AV} = \frac{{R}_{1}}{π} \cdot {\int }_{0}^{{α}_{1}} sin ( {ω}_{C} ) d α + \frac{{R}_{2}}{π} \cdot {\int }_{{α}_{2}}^{π } sin ( {ω}_{C} ) d α$$

As these are simple enough elementary functions, the average output current can be given analytically by:

$${I}_{out , AV} = \frac{{V}_{1}}{π {Z}_{C}} ( \frac{sin ( {α}_{2} ) + sin ( {α}_{1} )}{sin ( {α}_{2} - {α}_{1 } )} - 1 )$$

Again, the output quantities can be determined by a design dependent scaling parameter (V₁/Z_{C}) and the detection of two characteristic timing parameters α₁ and α₂. As the switching frequency is typically known beforehand as a result of converter control it is not necessary to measure the angle α₂ separately. Instead, it can be derived already from the switching frequency and the angle α₁.

Thus, it is now possible to determine the desired output value I_{out,AV} according to the above given formula based on α₁. As explained above, α₁ corresponds to the time interval t₁ defined between a switching event of the half bridge S_{1/}S₂ (negative edge of the half bridge voltage in FIG. 7) and the zero crossing of the inductor current I_{L}. t₁ may thus be determined in the apparatus of FIG. 1 by counting the clock pulses starting from the switching event S_{W} to the comparator event (comparator signal comp, comparing I_{L} to a reference of I_{ref}=0 changes). t₂ may be either measured (time duration from zero crossing to next switching event) by logical unit 24, or may be calculated from the known values of switching frequency and duty cycle in the given example. From these values, α₁ and α₂ may be calculated as defined above, so that calculation unit 30 may deliver the desired output current I_{out,AV}.

It has thus been shown for a multitude of converter topologies, including both resonant and non-resonant SMPS circuits, how evaluation of timing of comparator events may deliver the desired electrical output values. This method may be used for many different types of power supplies for different types of loads. If applies in particular to zero-current switching DC/DC converters for loads such as lamps, especially HID and UHP lamps. It also applies e. g. for resonant power converters, such as LLC, LLCC and other for LED driver, back lighting or medical applications.

The invention has been illustrated and described in detail in the drawings and foregoing description. Such illustration and description are to be considered illustrative or exemplary and not restrictive; the invention is not limited to the disclosed embodiments.

In the claims, the word “comprising” does not exclude other elements, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. Apparatus for determining an output voltage or output current in a power supply circuit (10) comprising a voltage input (14) and at least one switching element (18) which in operation is switched according to consecutive switching cycles, such said apparatus (12) comprising
a comparator (20) for comparing an electrical value (IL) within said power supply circuit (10) to a reference value (Iref), where said electrical value (IL) varies within said switching cycles such that is equal to said reference value (Iref) at least once during each cycle, said comparator (20) delivering a binary comparator signal (comp) depending on the comparison of said electrical value (IL) and said reference value (Iref),
means (24) for determining timing information (t) of at least one instance of change in said comparator signal (comp) within a switching cycle,
and means (30) for determining an output voltage (Vout,AV) or output current (Iout,AV) based on said timing information (t).

2. Apparatus according to claim 1, where
said reference value (Iref) is chosen to be constant at least within each of said cycles.

3. Apparatus according to claim 1, where
said output voltage (Vout,AV) or output current is a time average value at least for one of said cycles.

4. Apparatus according to claim 1, where
said timing information (t) comprises at least a timing value indicating the duration of a time interval between a switching instant of said switching element (18) and said instant of change of said comparator signal (comp).

5. Apparatus according claim 1, further comprising
a digital counter (24) which counts clock pulses within a time period that starts and/or ends with said instant of change in said comparator signal (comp).

6. Apparatus according to claim 1, where
a digital calculation unit (30) is provided for determining said output voltage (Vout,AV) or output current (Iout,AV) from said timing information.

7. Apparatus according to claim 1, where
said power supply circuit (10) comprises a voltage input (14) and at least one switching element (18) supplying an input voltage (V1) as a switched voltage to a reactive element (L, C) connected to an output part delivering said output voltage (Vout) or output current (Iout),
where said electrical value (IL) is a current through said reactive element (L) or a voltage over said reactive element.

8. Apparatus according to claim 7, where
said reactive element is an inductor (L),
and said comparator (20) compares a current through said inductor (L) to said reference value (Iref).

9. Apparatus according to claim 8, where
said inductor (L) is connected in series between said switching element (18) and an output part of said circuit (10) delivering said output voltage (Vout) or current (Iout).

10. Apparatus according to claim 1, where
said circuit (10) is a resonant circuit comprising a resonant element.

11. Power supply circuit comprising
a voltage input (14),
at least one switching element (18) which in operation is switched according to consecutive switching cycles,
and an apparatus (12) according to claim 1 for determining an output voltage (Vout,AV) or output current (Iout,AV).

12. Method for determining an output voltage or output current in a power supply circuit (10) comprising a voltage input (14) and at least one switching element (18), which in operation is switched according to consecutive switching cycles, said method comprising the steps of
comparing an electrical value (IL) within said power supply circuit (10) to a reference value (Iref), where said electrical value (IL) varies within said switching cycles such that it is equal to said reference value (Iref) at least once during each cycle, to deliver a comparator signal (comp) depending on the comparison of said electrical value (IL) and said reference value (Iref),
determining timing information (t) of at least one instant of change in said comparator signal (comp) within a switching cycle,
using said timing information (t) for determining said output voltage (Vout,AV) or output current (Iout,AV).
